(19) United States
(12) Patent Application Publication
(10) Pub. No.: US 2002/0067836 A1
(43) Pub. Date: Jun. 6, 2002

(54) Method and device for artificial reverberation

(76) Inventor: Shreyas Anand Paranjpe, Oakland, CA (US)

Correspondence Address: Andre L. Marais, BLAKELY, SOKOLOFF, TAYLOR & ZAFMAN LLP, Seventh Floor, 12400 Wilshire Boulevard, Los Angeles, CA, 90025-1026, US

(21) Appl. No.: 09/924,733

(22) Filed: Aug. 7, 2001

Related U.S. Application Data
(60) Provisional application No. 60/243,200, filed on Oct. 24, 2000.

(51) Int. Cl. H03G 3/00

(52) U.S. Cl. 381/63

(57) ABSTRACT

A reverberation device is provided for adding a reverberation signal to an audio input signal. The device consists of a late reflection generator and an early reflection generator which share common delay line memory. Sparsely selected taps are utilized to generate an early reflection signal from the input signal as it passes through the delay line. Subsequently, the delayed signal is attenuated and recirculated, and multiple randomly selected taps are utilized to generate a late reflection signal with enhanced echo density. The late reflection and early reflection signals are combined with the input signal to generate an output signal with added reverberation.

### CROSS REFERENCE TO RELATED APPLICATIONS

This application claims the benefit of U.S. Provisional Application No. 60/243,200 filed Oct. 24,2000.

### FIELD OF THE INVENTION

The present invention relates to reverberation apparatus which adds reverberation to an audio signal passing through the apparatus.

### BACKGROUND OF THE INVENTION

Reverberation is the complicated set of reflections that are produced when a sound travels from a source to a listener by bouncing off many different surfaces. We spend our lives in reverberant environments, surrounded by objects such as walls, floors, ceilings, desks, windows, furniture, etc. that reflect sound. These reflections provide important signals to our brain that describe our environment and allows us to distinguish, for example, whether we are in a small bathroom or a large stadium.

An artificial reverberation device, also referred to as a reverb, can be used in conjunction with audio reproduction equipment to effectively transform a listening environment to provide a more enjoyable listening experience. Music that is processed by a reverb can transform an ordinary living room into a virtual world-class concert hall, thus providing a more satisfying listening experience to a user of the device.

Developing artificial reverbs that simulate real and imagined environments is a complicated and nontrivial endeavor. Practical constraints such as limited delay line memory and processing power must also be considered. Bad reverbs are relatively easy to design. Unfortunately, a bad reverb is often worse than having no reverb at all. Bad reverbs can muddy, color, or distort the sound enough to diminish the listening experience and can be objectionable and annoying.

Prior art reverberation devices have the following shortcomings. Series and/or parallel combinations of comb and allpass filters as described in an article by J. A. Moorer entitled “About this Reverberation Business” (Computer Music Journal, pp 13-28, Vol 3, No. 2, 1979) suffer from various problems such as flutter echo and ringing in the decay. Furthermore, choosing the appropriate delay line lengths and filter coefficients is difficult and largely empirical. Typically, incommensurate delay lengths (that is, lengths which are mutually prime) are suggested in order to reduce any obvious reflection patterns.

Feedback delay networks (FDNs) as described in an article by John Stautner and Miller Puckette entitled “Designing Multi-Channel Reverberators” (Computer Music Journal, pp.569-582, Vol 6, No. 1, Spring 1982) can be designed to be guaranteed stable, but also suffer from flutter and tonal coloration in the decay. They suggest continuously varying the delay line lengths randomly to reduce flutter and tonal coloration.

A more formalized analytical approach that reduces some of the empirical nature of reverb design, is described by Jean-Marc Jot and Antoine Chaigne in an article entitled “Digital delay networks for designing artificial reverberators” (Proceedings of the 90^{th} AES Convention, 1991). This design also relies on FDNs. Even though those designs can produce natural sounding reverberation, they still require a large amount of memory and close attention in selecting delay line lengths.

A design proposed by Riitta Vaananen, Vesa Valimaki, Jyri Huopaniemi and Matti Karjalainen in an article entitled “Efficient and Parametric Reverberator for Room Acoustics Modeling” (Proceedings of the ICMC97, September 1997) reduces the amount of memory required by combining elements of the above referenced designs but thereby reduce the theoretical modal density and increase the difficulty in choosing delay line lengths in order to prevent tonal coloration. U.S. Pat. No. 4,268,717 of Christopher H. Moore entitled “Time-modulated delay system and improved reverberation simulator using same,” granted May 19, 1981 describes the use of multiple time varying feedback taps to help increase echo density, but at the expense of introducing pitch modulation and other distortions. Unfortunately, feedback from multiple taps can cause the reverberator to become unstable and should thus be avoided, as described in an article by P. E. Axon, C. L. S Gilford and D. E. L Shorter entitled “Artificial Reverberation” (Proceedings of the IEE, Part B, p 624-640, Feb. 1955) and later again in an article by David Griesinger entitled “Practical Processors and Programs for Digital Reverberation” (Proceedings of the AES 7^{th} International Conference, p 187-195, 1989).

Prior art reverberation devices tend to suffer from various combinations of bad sound, the need for too much delay line memory, and/or require difficult design procedures.

### BRIEF DESCRIPTION OF THE DRAWINGS

The features and advantages of the present invention will be more fully understood by reference to the accompanying drawings, in which:

FIG. 1 shows a simplified block diagram of a reverberation device according to the present invention;

FIG. 2 shows a functional block diagram of a late reflection generator of the device, for a four input/output audio system;

FIG. 3 shows a block diagram illustrating the delay line topology for a two input/output system;

FIG. 4 shows a block diagram illustrating the delay line topology for a four input/output system comprising a pair of two input/output systems as per FIG. 3; and

FIG. 5 shows a functional block diagram of an early reflection generator of the device.

### DETAILED DESCRIPTION

In the following description, for the purposes of explanation and illustration, numerous specific details are set forth in order to provide a thorough understanding of the present invention. However, it will be obvious to one skilled in the art that the present invention may be practiced without the specific details. Further, the provided details provide only exemplary embodiments of the present invention.

The reflections generated in reverberant environments are lumped into two groups: “early reflections” occur within the first 60 to 80 milliseconds after the original sound; “late reflections” occur thereafter. Artificial reverberation devices therefore often have one unit to generate early reflections and another to generate late reflections. Because the early reflections occur over a finite time duration, they are often simulated using finite impulse response (FIR) filters with a sparse number of taps. The late reflections, however, may persist for a much longer time. The “reverberation time” of an environment is one type of measurement that determines how long the late reflections persist. Concert halls typically have reverberation times of 1.5 to 3 seconds; artificial acoustic spaces may have much longer, possibly even infinite reverberation times. The longer the reverberation time, the greater the delay time memory required to simulate it. Because it is impractical to use such a large amount of delay line memory to directly synthesize the late reflections, the late reflections generator typically uses infinite impulse response (IIR) filters. That is, the delay lines use feedback and attenuation to recirculate the signal and control its decay.

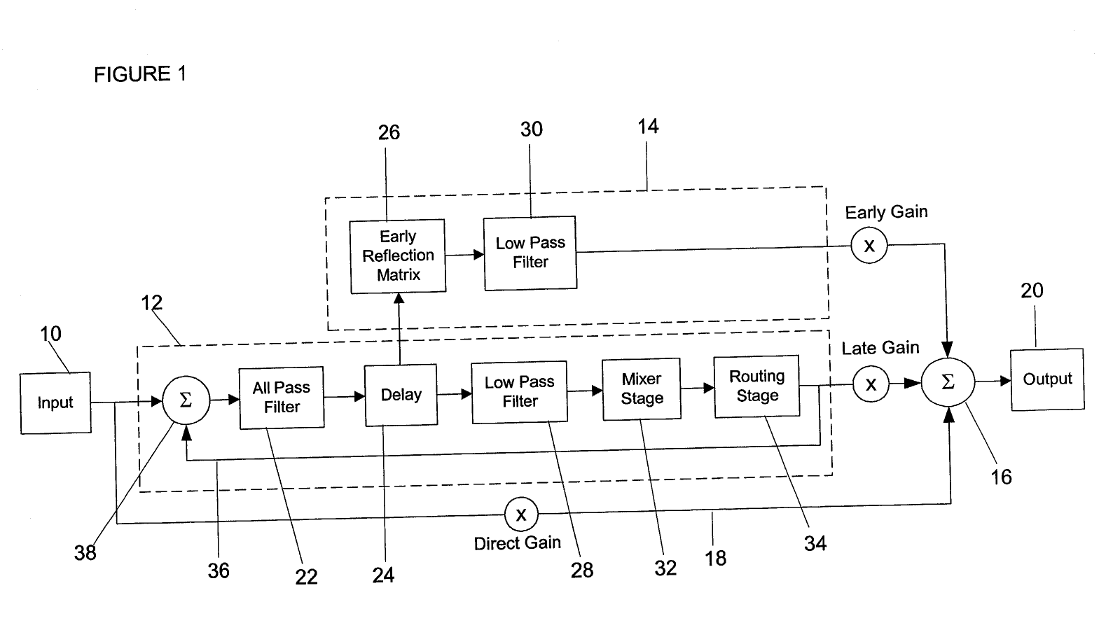

The high level block diagram of FIG. 1 shows the basic arrangement of one embodiment of the reverberation device of the invention. The device comprises an input 10 which can receive audio frequency signals which are to be processed by the device, a late reflection generator 12 which generates late reflection signals, and an early reflection generator 14 which generates early reflection signals. The late and early reflection signals are added in a summation block 16 together with the original input signal which is fed to the summation block via a direct feed 18. The summed or combined signal comprising all three components is fed to an output 20, from where the processed signal can be fed to a further audio component, such as an amplifier.

The reverberator can be implemented digitally by a programmable processor (including a digital signal processor) or a custom integrated circuit. This reverberator can be used with signals in the full audio spectrum (20 Hz to 20 kHz) that have been suitably converted from analog to digital, using analog-to-digital (A/D) converters, to feed the reverberator input. The outputs may be converted from digital to analog, using digital-to-analog (D/A) converters, and then sent to an amplifier and speakers for immediate audition, or left in digital form for storage or further digital processing.

There are many different environments where this artificial reverberator can be used, as indicated by the following examples. In a home theater system, a multi-channel audio soundtrack can be sent directly from the audio source (which is often a DVD player) to the reverberation device. The digital outputs from the reverberation device can be converted to an analog signal and then be sent to an amplifier and onwards to a set of speakers. In a music studio environment, the outputs from various musical instruments can be digitized and then sent to the reverberation device. The outputs of the device may be left in digital form if the signal is then used to create a digital audio compact disc, for example.

The late reflection generator 12 comprises an all pass filter 22 preceding a delay line set 24. The delay line set 24 comprises at least two delay lines, with cross-feeding taps. The delay line set 24 has multiple outputs which are fed both to an early reflection matrix 26 in the early reflection generator 14 and to a low pass filter 28 in the late reflection generator. The output of the early reflection matrix 26 is fed via a low pass filter 30 to the summation block 16, as the output of the early reflection generator 14.

The output of the low pass filter 28 is fed to a mixer stage 32 and then via a routing stage 34 to the summation block 16. A feedback loop 36 recirculates the output of the routing stage 34 back to the input of the late reflection generator via a summation block 38, so that the attenuated, delayed signal can be recirculated in the late reflection generator. Each path of the device has its own respective gain stage.

The design considerations of the late reflection generator will now be described in greater detail.

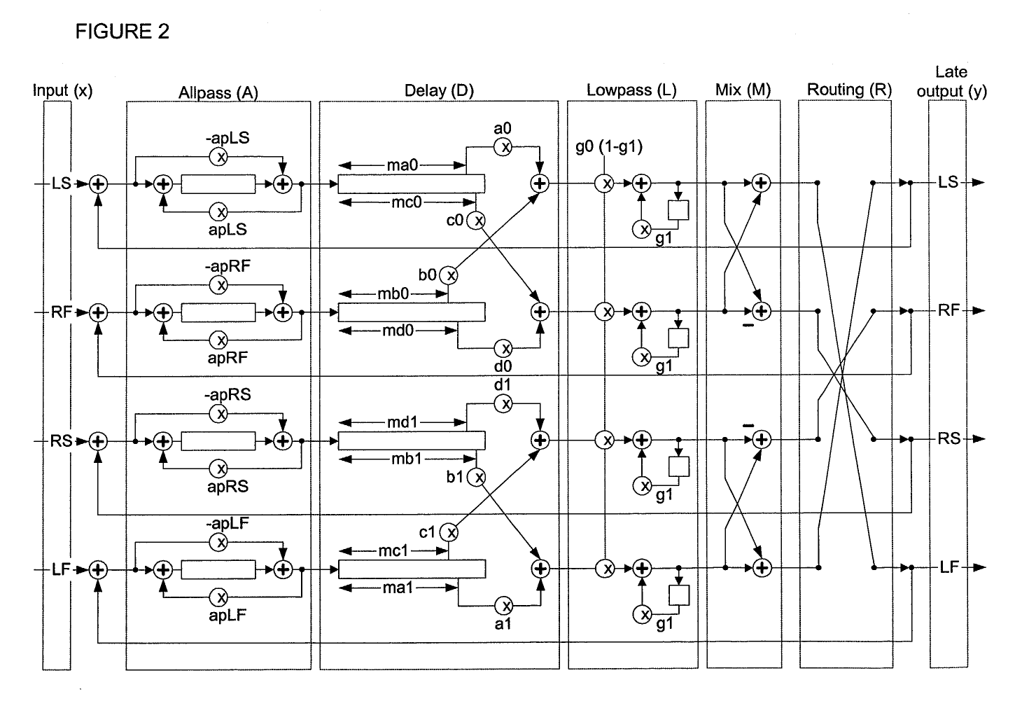

The late reflections are generated by recirculating the input signal through a circuit modeled as a lossless prototype. The lossless prototype is an energy conserving system based on a unitary system (i.e. energy in equals energy out) with feedback. After the input signal is injected into the lossless prototype system, it never decays as it recirculates. However, in real acoustic spaces, the late reflections eventually decay, and the frequency dependent absorption that results, when sound propagates through air and is reflected off surfaces, is modeled by inserting lowpass filters into the lossless prototype. As long as the lossless prototype is unitary, and the magnitude of the absorptive losses is less than unity, then the system is stable. The input and output of the late reflection generator can be described using the following vector and matrix equations, with reference to the more detailed block diagram of FIG. 2. Note that a unitary system is represented by a unitary matrix, and we rely on the fact that since the product of unitary matrices results in another unitary matrix, then the series cascade of unitary systems is also another unitary system.

A matrix, U, is unitary when the matrix times the transpose of the complex conjugate of the matrix produces the identity matrix, I. Algebraically, this is described by

_T

U·U=I

The overbar represents taking the complex conjugate of U, and the superscript T represents taking the transpose of U. In FIG. 2, a 4×4 audio system (a system having four inputs and four outputs) is shown. Such a system has four loudspeakers, two front speakers and two rear or surround speakers. The signals intended for these speakers are labeled accordingly as LF for left front, RF for right front, LS for left surround, and RS for right surround.

The input signal is represented by the column vector, x, and the late reflections by the column vector, y. The matrices represent the various transformations that are applied to the signal. The allpass filter is represented by the matrix A. The novel delay line topology is represented by the matrix D. The lowpass filter is represented by the matrix L. The delayed and filtered signals are combined according to the mixing matrix M. After the delayed and filtered signals are combined, they are fed back to the input according to the routing matrix R.

The late output signal, y, (that is, the late reflection signal) is described in terms of the input signal, x, by the following equation:

y=(I−R·M·L·D·A)⁻¹·R·M·L·D·A·x

The lossless prototype system is defined by the matrix transformations given by R M D A. As long as each of these matrices is unitary, then cascading them in series produces another unitary matrix. The frequency dependent absorption that results, when sound propagates through air and reflects off surfaces, is modelled by the lossy lowpass filters represented by the matrix L; the L matrix should not be unitary.

The function of each section of the late reflection generator and its corresponding defining matrix will now be described. The allpass filter (A) increases echo density and can also be used to add realism to the early reflections.

The delay line topology of the present invention provides the following three important features: multiple output taps, time varying output taps, and guaranteed stability. Multiple output taps increase echo density because for every one pulse that enters this topology, multiple pulses exit. This provides a more realistic room simulation because echo density increases as time progresses, as it does in the real world. Furthermore, the multiple output taps are allowed to change position and amplitude; that is, the delay line lengths and coefficients are time variant. By varying the delay line lengths and coefficients, the resonant frequencies change, thus reducing coloration and fluttering and allowing the use of less delay line memory than a time invariant reverberation algorithm. Coloration is reduced because no one set of modes persists any longer than any other neighboring set of modes. As long as there is at least one lossy element somewhere in the recirculating system, this delay line topology is guaranteed to be stable because it is unitary. (The lowpass filter, L, described in more detail below, is the lossy element in the recirculating system.) In order to achieve a unitary system with multiple taps in the delay line topology, a set of at least two delay lines is needed.

In prior art systems, echo density is increased by increasing the number of nonzero coefficients in the feedback matrix, and coloration is reduced by choosing incommensurate delay line lengths. Known feedback delay network (FDN) reverberators use a similar delay line topology: multiple delay lines are used, where each delay line has a single output tap. The prior art delay line topology is represented by a matrix where the only entries are delay elements along the matrix's principal diagonal as shown by the following matrix, where z^{-m} represents a time delay of m samples:

$$D = [ \begin{matrix}{z}^{- ma} & 0 & 0 & 0 \\ 0 & {z}^{- mb} & 0 & 0 \\ 0 & 0 & {z}^{- m c} & 0 \\ 0 & 0 & 0 & {z}^{- md}\end{matrix} ]$$

In prior art systems that attempted to use multiple output taps from the same delay line, the following equations show why their delay line topology was not unitary, and it is therefore not surprising that they experienced unstable systems that were controllable using low feedback values.

$$D = a \cdot {z}^{- ma} + b \cdot {z}^{- mb} {\overline{D}}^{T} = a \cdot {z}^{m a} + b \cdot {z}^{mb}$$

The product simplifies to

$$D \cdot {\overline{D}}^{T} = {a}^{2} + {b}^{2} + a \cdot b \cdot ( {z}^{- ma + mb} + {z}^{- mb + ma} )$$

Evaluating the above product on the unit circle (by substituting z=ei^{ω}) produces the following result which cannot be unity for all frequencies.

a²+b²+2·a·b·cos (ω·(ma−mb))

Even if that approach were extended to a feedback delay network (instead of just a single delay line), feeding back multiple taps to the same delay line does not allow for a unitary system.

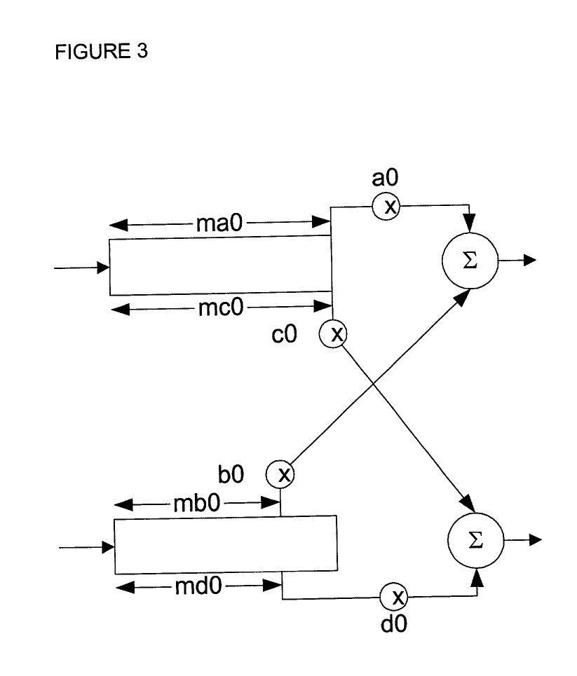

The design approach of the present invention allows for multiple taps from the same delay line as long as certain restrictions are fulfilled. For example, for a 2×2 system that has 2 inputs, 2 delay lines, and 2 outputs (see FIG. 3), the delay line topology and the corresponding delay matrix, D, are as follows:

$$D = [ \begin{matrix}a0 \cdot {z}^{- ma0} & b0 \cdot {z}^{- mb0} \\ c0 \cdot {z}^{- mc0} & d0 \cdot {z}^{- md0}\end{matrix} ]$$

In order for the delay line topology to be unitary, the delay matrix D must satisfy the constraint

$$D \cdot {\overline{D}}^{T} = I$$

The left hand side of the equation simplifies to

$$[ \begin{matrix}{a0}^{2} + {b0}^{2} & a0 \cdot c0 \cdot {z}^{- ma0 + mc0} + b0 \cdot d0 \cdot {z}^{- mb0 + md0} \\ a0 \cdot c0 \cdot {z}^{- mc0 + ma0} + b0 \cdot d0 \cdot {z}^{- md0 + mb0} & {c0}^{2} + {d0}^{2}\end{matrix} ]$$

The above matrix is unitary provided the following constraints are fulfilled: the elements along the diagonal must equal unity while all other elements must cancel to zero. For the simple 2×2 case, we can easily satisfy these constraints using the following values for the coefficients (a0, b0, c0, d0) and delay line lengths (ma0, mb0, mc0, md0):

a0=cos (θ) b0=sin (θ)

c0=sin (θ) d0=−cos (θ)

ma0+md0=mb0+mc0

The delay line topology of the present invention has entries off the main diagonal (represented by b0 z^{-mb0} and c0 z^{-mc0}), thus we have multiple output taps from the same delay line set. By satisfying the above design constraints, the delay line topology is unitary, and when placed in a larger system that includes at least some lossy elements, the overall system stability is guaranteed.

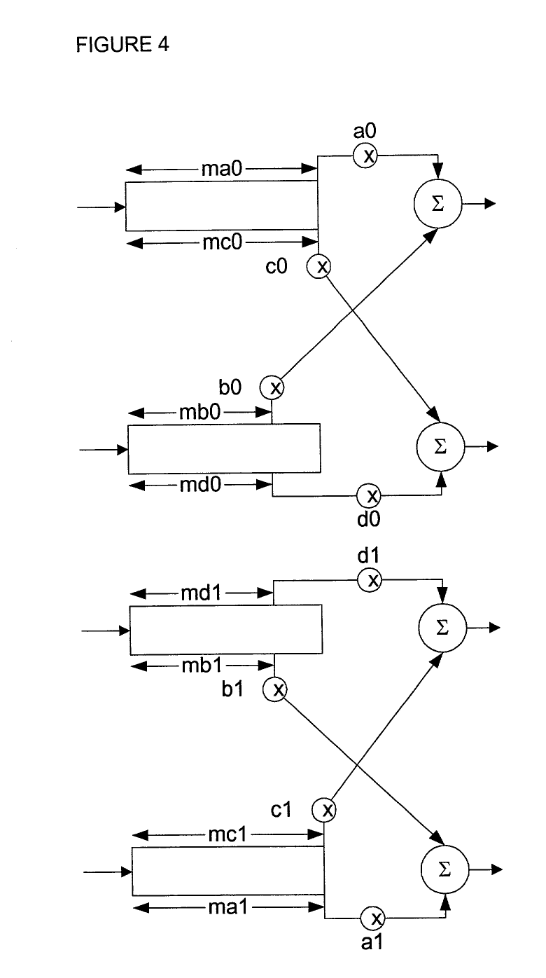

The 2×2 system can easily be extended to a larger system. For example, one way of designing a 4×4 system is to use two 2×2 systems (see FIG. 4) with the corresponding matrix:

$$D = [ \begin{matrix}a0 \cdot {z}^{- ma0} & b0 \cdot {z}^{- mb0} & 0 & 0 \\ c0 \cdot {z}^{- mc0} & d0 \cdot {z}^{- md0} & 0 & 0 \\ 0 & 0 & d1 \cdot {z}^{- md1} & c1 \cdot {z}^{- mc1} \\ 0 & 0 & b1 \cdot {z}^{- mb1} & a1 \cdot {z}^{- ma1}\end{matrix} ]$$

In order for the delay line topology to be unitary, the delay matrix D must satisfy the constraint

$$D \cdot {\overline{D}}^{T} = I$$

The left hand side of the equation yields

$$[ \begin{matrix}a0 \cdot {z}^{- ma0} & b0 \cdot {z}^{- mb0} & 0 & 0 \\ c0 \cdot {z}^{- mc0} & d0 \cdot {z}^{- md0} & 0 & 0 \\ 0 & 0 & d1 \cdot {z}^{- md1} & c1 \cdot {z}^{- mc1} \\ 0 & 0 & b1 \cdot {z}^{- mb1} & a1 \cdot {z}^{- ma1}\end{matrix} ] \cdot \begin{matrix}[ \begin{matrix}a0 \cdot {z}^{ma0} & c0 \cdot {z}^{mc0} & 0 & 0 \\ b0 \cdot {z}^{mb0} & d0 \cdot {z}^{md0} & 0 & 0 \\ 0 & 0 & d1 \cdot {z}^{md1} & b1 \cdot {z}^{mb1} \\ 0 & 0 & c1 \cdot {z}^{mc1} & a1 \cdot {z}^{ma1}\end{matrix} ]\end{matrix}$$

which simplifies to

$$[ \begin{matrix}{a0}^{2} + {b0}^{2} & a0 \cdot c0 \cdot {z}^{- ma0 + mc0} + b0 \cdot d0 \cdot {z}^{- mb0 + md0} & 0 & 0 \\ a0 \cdot c0 \cdot {z}^{- mc0 + ma0} + b0 \cdot d0 \cdot {z}^{- md0 + mb0} & {c0}^{2} + {d0}^{2} & 0 & 0 \\ 0 & 0 & {d1}^{2} + {c1}^{2} & b1 \cdot d1 \cdot {z}^{- md1 + mb1} + a1 \cdot c1 \cdot {z}^{- mc1 + ma1} \\ 0 & 0 & b1 \cdot d1 \cdot {z}^{- mb1 + md1} + a1 \cdot c1 \cdot {z}^{- ma1 + mc1} & {b1}^{2} + {a1}^{2}\end{matrix} ]$$

Again, the above matrix is unitary provided the following constraints are fulfilled: the elements along the main diagonal must equal unity while all other elements must cancel to zero. Because this simple 4×4 case is constructed of two separate 2×2 systems, we can easily satisfy these constraints using the following set of values for the coefficients and delay line lengths, similarly to the 2×2 case:

a0=cos (θ) b0=sin (θ) a1=cos (Φ) b1=sin (Φ)

c0=sin (θ) d0=−cos (θ) c1=sin (Φ) d1=−cos (Φ)

ma0+md0=mb0+mc0ma1+md1=mb1+mc1

By using cosine and sine for our coefficients (a0, b0, c0, d0; a1, b1, c1, d1), the coefficients can be parameterized as functions of time. That is, as the cosine and sine phase angle changes over time, the coefficient values also change but the unitary matrix constraints for the coefficients are still fulfilled.

The delay line length constraints indicate that for each 2×2 system, the sum of the delay line lengths for the terms on the principal diagonal must equal the sum of the delay line lengths for the terms on the anti-diagonal. The actual delay line lengths can be any positive real numbers that satisfy the above criteria, but for purposes of the described embodiment, typical listening room geometry and psychoacoustics are assumed to set the delay line lengths. Since the early reflections in a concert hall occur during the first 60 to 80 milliseconds and the late reflections thereafter, the delay line lengths should correspond nominally to 60 to 80 milliseconds. For practical constraints, a maximum delay line length of 65 milliseconds was chosen. By choosing 65 milliseconds as the maximum delay line length for each delay line, the same delay line set is used to both directly generate the early reflections and indirectly generate the late reflections. The early reflections are generated by sparsely placing taps along the delay lines.

What is generally meant by “sparsely placed taps” is that the taps are spread apart by many, or at least more than one, delay unit. Expressed in a more mathematical format, a time delay of one unit (ie. one sample) is represented by Z⁻¹ and a time delay of M units (ie. M samples) is represented by Z^{-m}. In the context of this specification, the concept of sparsely placing taps along the delay lines means that each tap is represented by Z^{-m}, where m does not equal one. In the case of the early reflection generator, m is of the order of 250 to 800. At a sampling frequency of 48 kHz, 250 samples corresponds to approximately 5 milliseconds, while 800 samples corresponds to 20 milliseconds. In other words, the early reflection generator has taps which are spread apart by approximately 5 to 20 milliseconds. By contrast, if the early reflection taps were placed at successive sample locations, this would be considered dense placement of the taps. As the input signal progresses through the delay line set for the first time, the taps simulate the early reflections. After exiting the delay line network, the signal is then attenuated and fed back to the input and recirculated to simulate the late reflections. The delay line lengths, however, can also change as time progresses as long as the delay line length constraints are fulfilled.

In the case of the late reflection generator, the output taps are spaced about 65 milliseconds away from the input, corresponding to a value for m in the region of 3000.

It has been proposed to vary the delay line lengths in prior art reverberators either completely randomly or with a periodic motion. The delay line topology of the present invention modulates the delay line lengths with a random number, as shown by the following equations, such that the delay line length constraint is always satisfied and that the maximum delay line length of 65 milliseconds is never exceeded.

ma0=maxLength−randomValue(n)

mb0=maxLength−randomValue(p)

mc0=maxLength−maxRandomValue+randomValue(p)

md0=maxLength−maxRandomValue+randomValue(n)

ma1=maxLength−randomValue(q)

mb1=maxLength−randomValue(r)

mc1=maxlength−maxRandomValue+randomValue(r)

md1=maxLength−maxRandomValue+randomValue(q)

The random value can be a function of time, such that

randomValue(i)≠randomValue(j)

for all time instants

i≠j

and should also be bounded such that

randomValue(t)<maxRandomValue

The lowpass filter of FIG. 2 is represented by the matrix, L, and is the only lossy element for the recirculating system. The lowpass filter provides a frequency dependent gain that simulates the absorption of sound as it propagates through air and reflects off surfaces. A simple single pole, no zero lowpass filter provides adequate control of the reverb time as a function of frequency. Higher order lowpass filters may be used if more control is desired.

Because each channel's delay line length is on average identical, since random numbers are added to the nominal delay line lengths, one lowpass filter per channel with identical feedback and feedforward gain values may be used. For the four channel case as shown in FIG. 2, the lowpass matrix transfer function is given below. The gain g0 controls the reverb time at DC, and the gain g1 controls the reverb time at another arbitrary frequency.

$$L = g0 \cdot [ \begin{matrix}\frac{1 - g1}{1 - g1 \cdot {z}^{- 1}} & 0 & 0 & 0 \\ 0 & \frac{1 - g1}{1 - g1 \cdot {z}^{- 1}} & 0 & 0 \\ 0 & 0 & \frac{1 - g1}{1 - g1 \cdot {z}^{- 1}} & 0 \\ 0 & 0 & 0 & \frac{1 - g1}{1 - g1 \cdot {z}^{- 1}}\end{matrix} ]$$

The delayed and filtered signals are combined according to the mixing matrix, M, and then fed back to the input according to the routing matrix, R, as shown in the following equations.

$$M = \frac{1}{\sqrt{2}} \cdot [ \begin{matrix}1 & 1 & 0 & 0 \\ 1 & - 1 & 0 & 0 \\ 0 & 0 & - 1 & 1 \\ 0 & 0 & 1 & 1\end{matrix} ]$$

$$R = [ \begin{matrix}0 & 0 & 0 & 1 \\ 0 & 0 & 1 & 0 \\ 0 & 1 & 0 & 0 \\ 1 & 0 & 0 & 0\end{matrix} ]$$

The constant gain term of 1/sqrt(2) normalizes the mixing matrix calculation and is required to ensure unitarity. For computational efficiency, this normalization term can be combined with the lowpass filter's feedforward coefficient.

The mixing and routing matrices ensure that some portion of the delayed input is always propagated in a common sense fashion. For example, in a 4 input, 4 output system, after the early reflections for the left front signal are generated, some portion of the left front signal is then sent to the right front and left surround delay lines to produce the late reflections. Even when the time varying delay matrix has output taps that are exclusively cross coupled or exclusively forward coupled, some portion of the input signal will always propagate to the nearest two adjacent speakers.

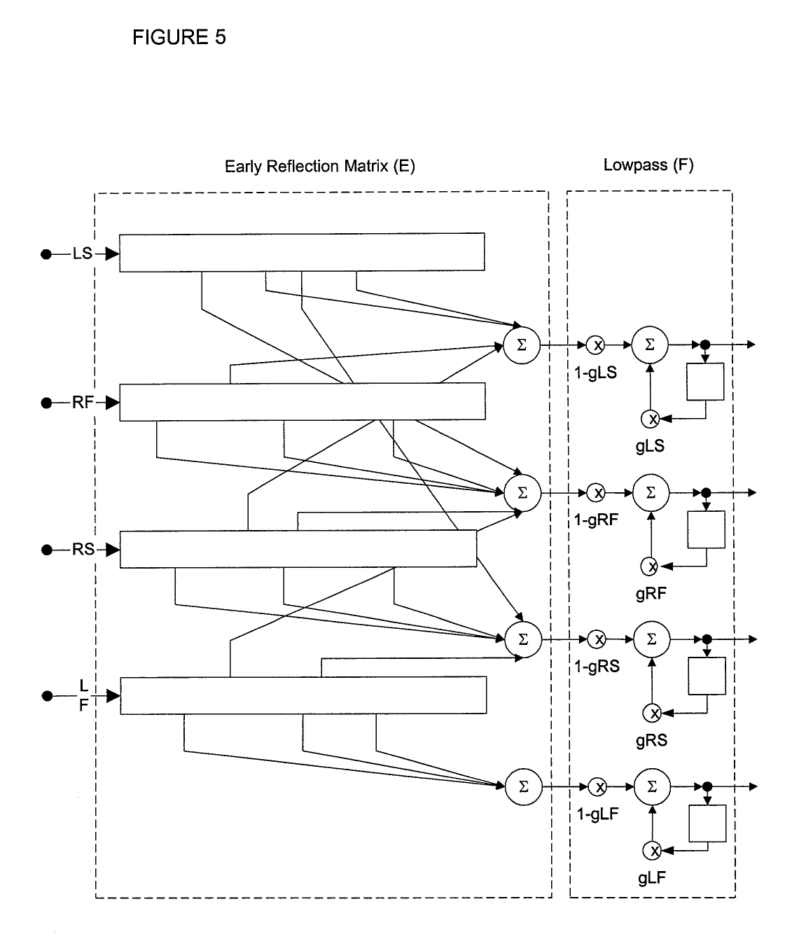

The early reflection generator is now described in greater detail with reference to FIG. 5.

As indicated above, the early reflection generator shares the delay line memory of the reverberation device with the late reflection generator, thus reducing the total memory required by the device. The early reflection signal obtained directly from the sparse output taps which are applied when the input signal first passes through the delay line is processed according to the early reflection matrix E. In this regard, FIG. 5 indicates a plurality of sets of delay lines, one each for the left front (LF), right front (RF), left surround (LS) and right surround (RS) signals.

Each delay line set may have multiple output taps that are summed to form a composite early reflection signal. The tap positions correspond to the delay times, and the tap weights correspond to the strength of the reflections. The tap positions and weights can be determined using a ray tracing model for the early reflections. The early reflections are generated as the input signal progresses through the delay lines for the first time. The input signal is combined, filtered, and fed back according to the D, L, M, and R matrices, sent through the allpass filters again (A matrix), and sent out using the same taps used for the early reflections. That is, the early reflection taps are re-used to generate the late reflections as the input signal recirculates through the entire structure.

The lowpass filters in matrix F provide additional realism by simulating sound absorption.

As described above, the reverberation device of the present invention utilizes a novel delay line topology which utilizes multiple output taps and time varying output taps and which is designed for guaranteed stability. Multiple output taps increase echo density because for every one pulse that enters this topology, multiple pulses exit. This provides a more realistic room simulation because echo density increases as time progresses, as it does in the real world. Furthermore, the multiple output taps are allowed to change position and amplitude; that is, the delay line lengths and coefficients are time variant. By varying the delay line lengths and coefficients, the resonant frequencies change, thus reducing coloration and fluttering and allowing the use of less delay line memory than a time invariant reverberation algorithm. Coloration is reduced because no one set of modes persists any longer than any other neighboring set of modes. As long as there is at least one lossy element somewhere in the recirculating system, the novel delay line topology is guaranteed to be stable because it is unitary.

The constraints for a unitary system are crucial, and must be satisfied at all times. For a 2×2 case, the following values for the coefficients (a0, b0, c0, d0) and delay line lengths (ma0, mb0, mc0, md0) satisfy the constraints:

a0=cos (θ) b0=sin (θ)

c0=sin (θ) d0=−cos (θ)

ma0+md0=mb0+mc0

The above values are not the only choices that satisfy the constraints. For example, we could switch the sin() values with the cos() values for a simple variation.

The 2×2 system can easily be extended to a larger system. For example, one way of designing a 4×4 system is to use two 2×2 systems. The delay matrix is unitary provided the following constraints are fulfilled for the product of the delay matrix and its conjugate transpose: the elements along the main diagonal must equal unity while all other elements must cancel to zero. Because this simple 4×4 case is constructed of two separate 2×2 systems, these constraints may be satisfied using the following set of values for the coefficients and delay line lengths, similarly to the 2×2 case:

a0=cos (θ) b0=sin (θ) a1=cos (Φ) b1=sin (Φ)

c0=sin (θ) d0=−cos (θ) c1=sin (Φ) d1=−cos (Φ)

ma0+md0=mb0+mc0 ma1+md1=mb1+mc1

By using cosine and sine for our coefficients (a0, b0, c0, d0; a1, b1, c1, d1), the coefficients can be parameterized as functions of time. That is, as the cos() and sin() phase angle changes over time, the coefficient values also change but the unitary matrix constraints for the coefficients are still fulfilled.

The delay line length constraints indicate that for each 2×2 system, the sum of the delay line lengths for the terms on the principal diagonal must equal the sum of the delay line lengths for the terms on the anti-diagonal. The actual delay line lengths can be any positive real numbers that satisfy the above criteria, but room geometry and psychoacoustics have been used in the exemplary embodiment to set the delay line lengths. Since the early reflections in a concert hall occur during the first 60 to 80 milliseconds and the late reflections thereafter, the delay line lengths should correspond nominally to 60 to 80 milliseconds. As described above, for practical constraints, a maximum delay line length of 65 milliseconds was chosen for the exemplary embodiment. By choosing 65 milliseconds as the maximum delay line length for each delay line, the same delay line set is used to both directly generate the early reflections and indirectly generate the late reflections. The early reflections are generated by sparsely placing taps along the delay lines. As the input signal progresses through the delay for the first time, the taps simulate the early reflections. After reaching the end of the delay line (65 milliseconds later, after the early reflections are done), the signal is then attenuated and fed back to the input and recirculates to simulate the late reflections. The delay line lengths, however, can also change as time progresses as long as the delay line length constraints are fulfilled.

Higher order systems, for example 6×6, 8×8, etc., can be constructed by adding individual 2×2 systems. Also, other delay matrices that have multiple taps for each element are possible, though satisfying the constraints becomes more difficult. For example, a 2×2 system with a total of 8 taps would have the following delay matrix:

$$D = [ \begin{matrix}a \cdot {z}^{- ma} + b \cdot {z}^{- mb} & c \cdot {z}^{- mc} + d \cdot {z}^{- md} \\ f \cdot {z}^{- mf} + g {z}^{- mg} & h \cdot {z}^{- mh} + k \cdot {z}^{- mk}\end{matrix} ]$$

This more complicated matrix would be unitary provided that

$$D \cdot {\overline{D}}^{T} = I$$

The left hand side expands to

$$[ \begin{matrix}a \cdot {z}^{- ma} + b \cdot {z}^{- mb} & c \cdot {z}^{- mc} + d \cdot {z}^{- md} \\ f \cdot {z}^{- mf} + g {z}^{- mg} & h \cdot {z}^{- mh} + k \cdot {z}^{- mk}\end{matrix} ] \cdot [ \begin{matrix}a \cdot {z}^{ma} + b \cdot {z}^{mb} & f \cdot {z}^{mf} + g {z}^{mg} \\ c \cdot {z}^{mc} + d \cdot {z}^{md} & h \cdot {z}^{mh} + k \cdot {z}^{mk}\end{matrix} ]$$

The constraints on the product are that the elements on the main diagonal are unity and zero elsewhere. More complicated systems can be constructed by adding more taps (i.e., more delay elements for each entry in the matrix), combining more simple smaller matrices into larger matrices (e.g., combining 2×2 matrices into 4×4, 6×6, etc. matrices), or both.

Thus, a method and device for artificial reverberation have been described. Although the present invention has been described with reference to specific exemplary embodiments, it will be evident that various modifications and changes may be made to these embodiments without departing from the broader spirit and scope of the invention. Accordingly, the specification and drawings are to be regarded in an illustrative rather than a restrictive sense.

What is claimed is:

1. A reverberation device for adding a reverberation signal to an input signal, the device comprising:
an input to receive an audio frequency input signal;
a late reflection generator to generate a late reflection signal;
an early reflection generator to generate an early reflection signal;
a summation block to combine the input signal, the late reflection signal and the early reflection signal; and
an output to provide an output signal comprising the input signal combined with the late and early reflection signals,
wherein the late and early reflection generators comprise a common set of delay lines arranged to output directly generated delay signals to the early reflection generator and to output recirculated delay signals to the late reflection generator.

2. A reverberation device according to claim 1 wherein the maximum length of each delay line is selected to correspond to the nominal period of early reflections.

3. A reverberation device according to claim 2 wherein each delay line has a length of 60 to 80 ms.

4. A reverberation device according to claim 3 wherein each delay line has a length of about 65 ms.

5. A reverberation device according to claim 1 wherein each delay line has multiple output taps, the taps being selectable relatively sparsely to generate a plurality of respective output tap signals which simulate early reflections.

6. A reverberation device according to claim 1 wherein each delay line has multiple output taps, the taps being selectable to vary the amplitude and delay of each of a plurality of respective output tap signals comprising the late reflection signal.

7. A reverberation device according to claim 6 wherein the combined signals from a plurality of output taps are attenuated and recirculated to increase the echo density of the late reflection signal.

8. A reverberation device according to claim 6 wherein the output taps are selectable randomly.

9. A reverberation device according to claim 6 wherein the delay line has multiple output taps that are selected such that the tap amplitudes and delays always comprise a unitary system.

10. A reverberation device according to claim 9 including an allpass filter, a lowpass filter, a mixer stage and a routing stage, wherein the allpass filter, the mixer stage and the routing stage are unitary systems and the lowpass filter is a lossy element.

11. A method of adding a reverberation signal to an input signal, the method comprising:
passing an input signal through a common set of delay lines having a plurality of selectable taps;
selecting a plurality of first taps to generate a first delayed signal for use as an early reflection signal;
selecting a plurality of second taps to generate a second recirculated delayed signal for use as a late reflection signal; and
combining the input signal, the early reflection signal and the late reflection signal.

12. A method according to claim 11 including selecting the maximum length of each delay line to correspond to the nominal period of early reflections.

13. A method according to claim 12 including selecting the length of each delay line to be in the range of 60 to 80 milliseconds.

14. A method according to claim 13 including selecting the length of each delay line length to be about 65 milliseconds.

15. A method to claim 11 wherein the plurality of first taps are selected relatively sparsely.

16. A method according to claim 11 wherein the plurality of second taps are selected to vary the amplitude and delay of each of a plurality of respective output tap signals comprising the late reflection signal.

17. A method according to claim 16 including combining the plurality of respective output tap signals, attenuating the combined signals, and recirculating the attenuated signals to increase the echo density of the late reflection signal.

18. A method according to claim 16 including selecting the plurality of second taps randomly.

19. A method according to claim 16 including selecting the plurality of second taps so that the tap amplitudes and delays always comprise a unitary system.
